(19) United States
(12) Patent Application Publication
(10) Pub. No.: US 2024/0121900 A1
(43) Pub. Date: Apr. 11, 2024

(54) CONDITION MONITORING DEVICE FOR A ROTATING MACHINE LINKED TO AN EXTERNAL POWER SUPPLY

(71) Applicant: Aktiebolaget SKF, Göteborg (SE)

(72) Inventors: Clément POULAILLEAU, Amboise (FR); Simon HUBERT, Tours (FR)

(21) Appl. No.: 18/475,716

(22) Filed: Sep. 27, 2023

(30) Foreign Application Priority Data
Oct. 6, 2022 (DE) 102022210541.9

(51) Int. Cl. H05K 1/18; G01H 1/00

(52) U.S. Cl. CPC H05K 1/181; G01H 1/003; H05K 2201/10151; H05K 2201/10409

(57) ABSTRACT

A condition monitoring device (2) that mounts on a machine. The condition monitoring device (2) includes a base (4), a circuit board (6), at least one sensor (8), and a connector 10. The base (4) is secured on the machine. The circuit board (6) is mechanically connected to the base (4). The at least one sensor (8) is mounted on the circuit board (6). The connector (10) is supported by the base (4) and connects the circuit board (6) to an external power supply (12).

### CROSS-REFERENCE TO RELATED APPLICATION

This application claims priority to German Application No. 102022210541.9, filed Oct. 6, 2022, the entirety of which is hereby incorporated by reference.

### FIELD

The present disclosure generally relates to a condition monitoring device, and in particular to condition monitoring sensors for monitoring the condition of a system such as a rotating machine. The system is for example electrically supplied by an internal source.

### BACKGROUND

Condition monitoring devices allow the condition of a system to be monitored without the need of manual inspection. These devices may be particularly advantageous in remote locations or locations which are difficult and/or dangerous to access, such as axles and/or bearings of a wide system of rotating machine.

The analysis of vibration signals produced by rotating machines is well known in the field of machine condition monitoring.

Generally, electrical sensors are used to gather vibration measurements that may then be analyzed to determine the machine condition and detect any machine defects.

In many situations, it may be convenient for the condition monitoring devices to be powered by an integrated generation source. Indeed, it may be necessary to provide electric energy and network connection to devices that are located in remote locations, for example where either power supply infrastructure does not exist or, if an infrastructure does exist, power is not available at the specific location where the device is installed.

To power condition monitoring devices, it is known to use an integrated battery in the condition monitoring device, the installation costs being highly reduced because of the absence of wiring.

However, the energy management is a major drawback of a condition monitoring device comprising a battery.

In some cases, as the battery is not rechargeable, the condition monitoring device wakes up every hour in order to save some battery. If the rotating machine is standing still while the condition monitoring device wakes up and makes a vibration measurement, the measurement is not relevant and the condition monitoring device is useless.

A condition monitoring device is generally incorporated in a mesh network comprising other condition monitoring devices and a gateway powered by an external power supply. All devices transmit their measurements to the gateway every hour. However, the external power supply may be a vehicle battery, which is often off. As a consequence, the measurements of the condition monitoring devices may all be lost because not transmitted to the gateway, and irrelevant because measured while the vehicle is turned off. The reconnection between the gateway and the devices could also take several hours.

There is thus a need to provide a condition monitoring device that can make measurement at any time and that works without energy management issues.

### SUMMARY

One object of the present disclosure is to provide a condition monitoring device configured to be mounted on a machine, the condition monitoring device comprising:
a base configured to be secured on the machine;
a circuit board mechanically connected to the base;
at least one sensor mounted on the circuit board; and
a connector supported by the base and provided to connect the circuit board to an external power supply.

The condition monitoring device has no power limit, it can thus measure the condition of the machine whenever it is useful, it can communicate more frequently and distantly and it can reconnect with a distant gateway more easily and rapidly as the external power supply is more able to furnish the power needed for the reconnection. The data transmission can still be done wirelessly.

In one embodiment, the connector comprises a DC-DC converter adapted to be linked to the external power supply.

In one particular embodiment, the connector is mounted on the circuit board.

Advantageously, the condition monitoring device comprises a casing mounted on the base and inside which is housed the circuit board.

Advantageously, the condition monitoring device further comprises a potting compound between the casing and the circuit board.

In an embodiment, the condition monitoring device comprises at least one fastener extending through the circuit board into the base.

Advantageously, the base comprises a first fixation portion configured to be fixed to the machine, and a second fixation portion comprising a wall parallel to the circuit board, wherein the circuit board is held against the second fixation portion by the at least one fastener.

Advantageously, the circuit board includes an antenna for wireless communication.

In one embodiment, the at least one sensor comprises a vibration sensor and/or a thermometer.

One other object of the present disclosure is to provide a kit comprising at least one condition monitoring device as previously defined, and an external power supply connected to the connector of said at least one condition monitoring device.

One other object of the present disclosure is to provide a mesh network comprising:
at least one condition monitoring device as previously defined and/or at least one kit as previously defined;
a gateway connected to a user interface and wirelessly communicating with said at least one condition monitoring device.

Advantageously, the mesh network comprises at least one autonomous condition monitoring device comprising a base configured to be secured on a machine, a circuit board mechanically connected to the base, at least one sensor mounted on the circuit board and an integrated power supply, the autonomous condition monitoring device being wirelessly connected to the gateway or to one condition monitoring device.

### BRIEF DESCRIPTION OF THE DRAWINGS

Other advantages and features of the present disclosure will appear from the detailed description of an embodiment of the present disclosure, which is a non-limiting example, illustrated on the appended drawings of which:

FIG. 1 is a schematic cross-section of a condition monitoring device according to the present disclosure linked to an external power supply; and

FIG. 2 is a schematic view of a mesh network comprising condition monitoring devices according to the present disclosure.

### DETAILED DESCRIPTION

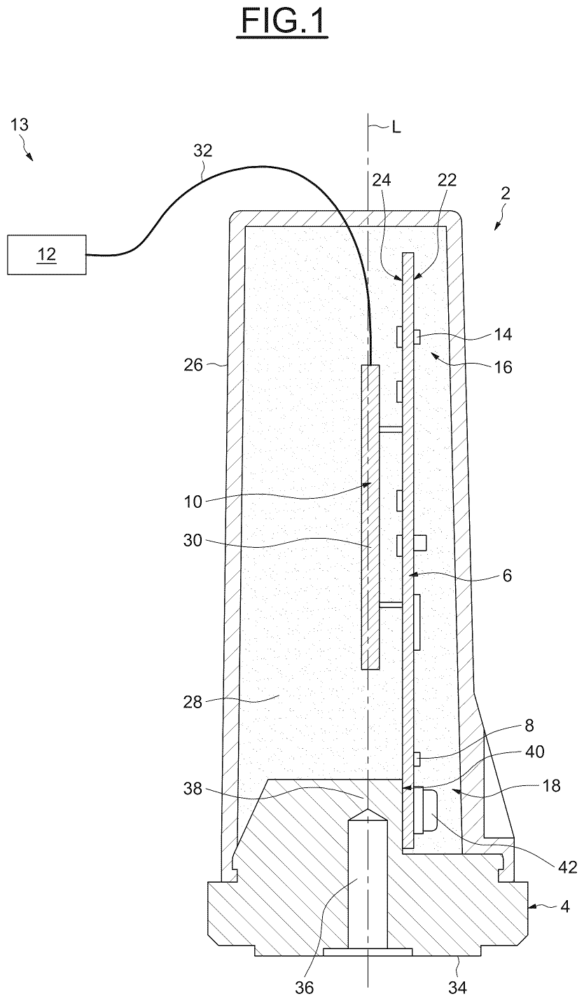

The FIG. 1 shows a condition monitoring device 2 that is designed to be mounted on a machine (not shown), for example on a housing of a rotating machine or in the vicinity of a rolling bearing.

The condition monitoring device 2 includes a base 4, for example made of metallic material, a printed circuit board 6 mounted mechanically on said base 4, at least one sensor 8 mounted on the circuit board 6, and a connector 10 supported by the base 4 and provided to connect the circuit board 6 to an external power supply 12. The circuit board 6 is supported by the base 4.

The external power supply 12 may be a vehicle battery, for example from a car or a harvester. The external power supply 12 does not form part of the device 2.

The external power supply 12 and the condition monitoring device 2 of the FIG. 1 are forming a kit 13. As a variant, a kit may include an external power supply 12 and several condition monitoring devices 2.

The circuit board 6 includes an antenna 14 for wireless communication, and the at least one sensor 8 comprises a vibration sensor, for example a piezoelectric element, a Micro Electro-Mechanical System or an accelerometer, and optionally a thermometer. As illustrated, the antenna 14 is located in the upper part 16 of the circuit board 6, the upper part being defined as the part of the circuit board 6 distal to the base 4.

The lower part 18 of the circuit board 6 is fixed to the base 4.

The circuit board 6 has a plate shape extending along a longitudinal axis L, the circuit board 6 comprising a first side 22 on which are disposed the at least one sensor 8 and the antenna 14, and an opposite second side 24.

The condition monitoring device 2 also comprises a casing 26 mounted on the base 4 and inside which is housed the circuit board 6. The casing 26 may be made from a material having high electromagnetic permeability, such as for example plastic, rubber or a resin.

The condition monitoring device 2 further comprises a potting compound 28 injected between the casing 26 and the circuit board 6 in order to rigidify and stabilize the circuit board 6. The potting compound 28 is, for example, made of a resin or a polymer injected through through-holes (not represented) made on the casing 26 inside the inner volume delimited in said casing 26.

The casing 26 thus covers and protects the potting compound 28, the circuit board 6, the antenna 14 and the at least one sensor 8.

The connector 10, also called adaptation board, comprises a DC-DC converter 30 adapted to be linked to the external power supply 12 by cables 32 from the connector 10. As illustrated, the connector 10 is mounted on the second side 24 of the circuit board 6. The connector 10 is thus supported by the base 4 through the circuit board 6. In one particular embodiment not illustrated, the connector 10 comprises the cables 32, said cables 32 comprising the DC-DC converter 30.

Advantageously, the cables 32 comprise a T-shaped connector (not illustrated) in order to plug the condition monitoring device to the external power supply 12 together with a previously plugged device.

When the external power supply 12 is a 12 Volts vehicle battery, the DC-DC converter 30 is used to convert 12 Volts in 3.6 Volts in order to supply the electronic of the condition monitoring device 2, which must be supplied by 3.6 Volts.

As a variant, the DC-DC converter 30 is used to convert any voltage in a voltage suitable for the supply of the condition monitoring device 2.

The base 4 comprises a first fixation portion 34 configured to be fixed to the machine. The first fixation portion 34 is substantially cylindrical and comprises a cavity 36 in which a fixation element of the machine can be introduced. For example, the fixation element is a screw.

The base 4 further comprises a second fixation portion 38 comprising a wall 40 parallel to the circuit board 6. More precisely, the wall 40 is held against the second side 24 of the circuit board 6. The condition monitoring device 2 comprises at least one fastener 42 extending through the circuit board 6 into the base 4, holding the circuit board 6 against the second fixation portion 38. For example, the at least one fastener 42 may be a screw inserted perpendicularly to the longitudinal axis L.

The vibrations of the machine are transferred from the machine to the base 4 and from the base 4 to the circuit board 6 and the vibration sensor 8 through the at least one fastener 42. In the illustrated embodiment, the measured vibrations are vibrations along the longitudinal axis L. The condition monitoring device 2 is preferably positioned along the periphery of a rotating machine so that the measured vibrations may be the vibrations emitted along the radius of the rotating machine.

The antenna 14 is used for wireless communication of the measures made by the at least one sensor 8. The communication is wireless in order to reduce the installation costs. The communication protocol uses a bidirectional mesh network at 2.4 GHz. This network is less energy consuming than Bluetooth and less perturbed by the surrounding electromagnetism.

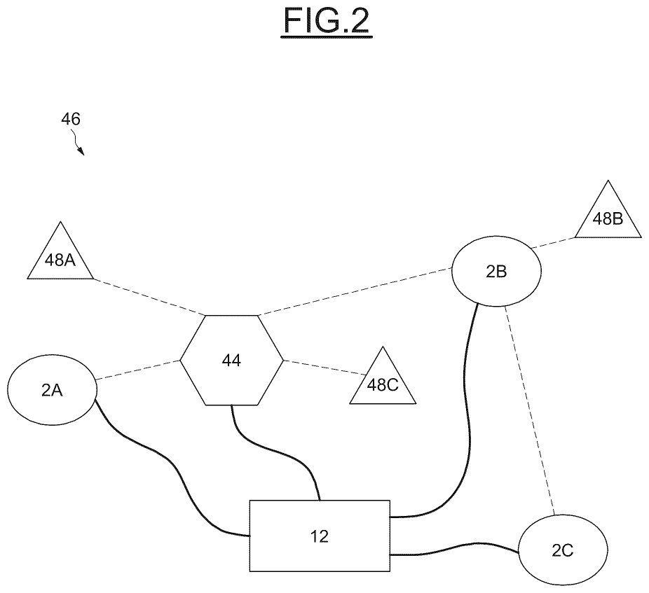

The condition monitoring device 2 is thus configured to acquire raw vibration signals produced by the machine, and to wirelessly transmit said vibration signals to a data center, for example via a gateway 44 illustrated in FIG. 2, in order to analyze the signals received and to determine the condition of the machine.

The FIG. 2 shows a mesh network 46 comprising three condition monitoring devices 2A, 2B, 2C, a gateway 44 connected to a user interface, for example via a data center, and an external power supply 12 supplying the gateway 44 and the condition monitoring devices 2A, 2B, 2C. The number of condition monitoring devices 2 may be different and extended to hundreds of devices.

Optionally, the mesh network 46 further comprises three autonomous condition monitoring devices 48A, 48B, 48C, each one comprising a battery. The number of autonomous condition monitoring devices may also be different. Each autonomous condition monitoring device has a similar architecture as the condition monitoring device 2 in order to facilitate the manufacturing process of the two devices, except that an autonomous condition monitoring device comprises an integrated power supply in addition of a base, a circuit board mechanically connected to the base, and at least one sensor mounted on the circuit board. Each autonomous condition monitoring device 48A, 48B, 48C is wirelessly connected to the gateway 44 or to one condition monitoring device 2.

The mesh network 46 is placed in a vehicle, the external power supply 12 being a vehicle battery, or in a factory, the external power supply 12 being a main power supply of the factory.

The condition monitoring devices 2A, 2B, 2C and the autonomous condition monitoring devices 48A, 48B, 48C permits to aggregate measurements from several machines or from several emplacements of a machine in a vehicle or in a factory.

The autonomous condition monitoring devices 48A, 48B, 48C are positioned in places which are difficult to access. However, their range for wireless communication is limited due to less available energy.

The condition monitoring devices 2A, 2B, 2C are wirelessly connected to the gateway and/or to other condition monitoring devices 2A, 2B, 2C and/or to autonomous condition monitoring devices 48A, 48B, 48C in order to relay their measurements to the gateway 44. The condition monitoring devices 2A, 2B, 2C being externally supplied, they have more power for a distant wireless communication. They can also be used as a relay for other condition monitoring devices 2A, 2B, 2C or autonomous condition monitoring devices 48A, 48B, 48C, as their cost is reduced compared to adding another gateway 44.

The condition monitoring devices 2A, 2B, 2C can also be used as a relay for other added sensors, for example a speed sensor or a magnetometer (not shown).

In the illustrated schematic embodiment, the autonomous condition monitoring device 48B and the condition monitoring device 2C have a wireless connection with the condition monitoring device 2B, which serves as a relay to the gateway 44.

What is claimed is:

1. A condition monitoring device configured to be mounted on a machine, the condition monitoring device comprising:
a base configured to be secured on the machine;
a circuit board mechanically connected to the base;
at least one sensor mounted on the circuit board; and
a connector supported by the base and configured to connect the circuit board to an external power supply.

2. The condition monitoring device according to claim 1, wherein the connector comprises a DC-DC converter adapted to be linked to the external power supply.

3. The condition monitoring device according to claim 1, wherein the connector is mounted on the circuit board.

4. The condition monitoring device according to claim 1, further comprising a casing mounted on the base and inside which is housed the circuit board.

5. The condition monitoring device according to claim 4, further comprising a potting compound between the casing and the circuit board.

6. The condition monitoring device according to claim 1, further comprising at least one fastener extending through the circuit board into the base.

7. The condition monitoring device according to claim 6, wherein the base comprises a first fixation portion configured to be fixed to the machine, and a second fixation portion comprising a wall parallel to the circuit board, wherein the circuit board is held against the second fixation portion by the at least one fastener.

8. A kit comprising:
at least one condition monitoring device according to claim 1, and
an external power supply connected to the connector of said at least one condition monitoring device.

9. A mesh network comprising:
at least one condition monitoring device according to claim 1;
a gateway connected to a user interface and wirelessly communicating with said at least one condition monitoring device.

10. The mesh network according to claim 9, further comprising at least one autonomous condition monitoring device comprising a base configured to be secured on a machine, a circuit board mechanically connected to the base, at least one sensor mounted on the circuit board and an integrated power supply, the autonomous condition monitoring device being wirelessly connected to the gateway or to one condition monitoring device.

11. The condition monitoring device according to claim 2, wherein the connector is mounted on the circuit board.

12. The condition monitoring device according to claim 11, further comprising a casing mounted on the base and inside which is housed the circuit board.

13. The condition monitoring device according to claim 12, further comprising a potting compound between the casing and the circuit board.

14. The condition monitoring device according to claim 13, further comprising at least one fastener extending through the circuit board into the base.

15. The condition monitoring device according to claim 14, wherein the base comprises a first fixation portion configured to be fixed to the machine, and a second fixation portion comprising a wall parallel to the circuit board, wherein the circuit board is held against the second fixation portion by the at least one fastener.

16. A kit comprising:
at least one condition monitoring device according to claim 15, and
an external power supply connected to the connector of said at least one condition monitoring device.

17. A mesh network comprising:
at least one kit according to claim 16;
a gateway connected to a user interface and wirelessly communicating with said at least one condition monitoring device.

18. The mesh network according to claim 17, further comprising at least one autonomous condition monitoring device comprising a base configured to be secured on a machine, a circuit board mechanically connected to the base, at least one sensor mounted on the circuit board and an integrated power supply, the autonomous condition monitoring device being wirelessly connected to the gateway or to one condition monitoring device.
